(19) United States
(12) Patent Application Publication
(10) Pub. No.: US 2026/0006779 A1
(43) Pub. Date: Jan. 1, 2026

(54) SEMICONDUCTOR STRUCTURE AND MANUFACTURING METHOD THEREOF

(71) Applicant: Powerchip Semiconductor Manufacturing Corporation, Hsinchu (TW)

(72) Inventors: Kuen Wei Sung, Hsinchu (TW); Hsin Tai, Hsinchu (TW); Yi-Hsuan Pai, Hsinchu (TW)

(73) Assignee: Powerchip Semiconductor Manufacturing Corporation, Hsinchu (TW)

(21) Appl. No.: 18/810,549

(22) Filed: Aug. 21, 2024

(30) Foreign Application Priority Data
Jul. 1, 2024 (TW) 113124585

(51) Int. Cl. H10B 12/00; H01L 21/762

(52) U.S. Cl. CPC H10B 12/50; H01L 21/76224; H10B 12/03; H10B 12/09; H10B 12/488

(57) ABSTRACT

A semiconductor structure and a manufacturing method thereof are provided. The semiconductor structure includes a substrate, a first dielectric layer, a storage node contact, a first dummy contact and a second dummy contact. The substrate has a memory device region and a peripheral region. The first dielectric layer is disposed on the substrate. The storage node contact is disposed in the first dielectric layer in the memory device region. The first dummy contact is disposed in the first dielectric layer in the memory device region and is adjacent to a boundary between the memory device region and the peripheral region. The second dummy contact is disposed in the first dielectric layer in the memory device region and is located between the first dummy contact and the storage node contact. The second dummy contact includes a second dielectric layer and a conductive layer located on the second dielectric layer.

### CROSS-REFERENCE TO RELATED APPLICATION

This application claims the priority benefit of Taiwan application serial no. 113124585, filed on Jul. 1, 2024. The entirety of the above-mentioned patent application is hereby incorporated by reference herein and made a part of this specification.

### BACKGROUND

### Technical Field

The present invention relates to a semiconductor structure and a manufacturing method thereof, and in particular to a manufacturing method of a semiconductor structure which may prevent the dummy contacts located in the memory device region from being damaged during the process, and the semiconductor structure manufactured by the manufacturing method.

### Description of Related Art

During the manufacturing process of the memory, dummy contacts are usually formed between the storage node contacts in the memory device region and the boundary between the memory device region and the peripheral region.

The forming method of the storage node contact and the dummy contact may include the following steps. First, the storage node contact hole and the dummy contact hole are formed in the dielectric layer, and the dielectric material has been formed in the storage node contact hole and the dummy contact hole. Next, a mask layer, such as a photoresist layer, is formed to cover the dummy contact hole, and a wet etching process is performed to remove the dielectric material in the storage node contact hole. After that, the mask layer is removed and the storage node contact hole is filled with the conductive material. The conductive material in the storage node contact hole may be used as the storage node contact, and the dielectric material in the dummy contact hole may be used as the dummy contact.

However, during removing the dielectric material in the storage node contact hole, the etchant used in the wet etching process penetrates into the dummy contact hole through the interface between the mask layer and the dielectric layer, causing the dummy contact to be etched and damaged.

### SUMMARY

The present invention provides a semiconductor structure, in which between the first dummy contact adjacent to the boundary between the memory device region and the peripheral region and the storage node contact, the second dummy contact constituted by a dielectric layer and a conductive layer is formed.

The present invention provides a manufacturing method of a semiconductor structure, in which the mask layer extends downward to the top surface of the dielectric pillar corresponding to the position of the second dummy contact to avoid the first dummy contact from being damaged in the etching process.

The semiconductor structure of the present invention includes a substrate, a first dielectric layer, a storage node contact, a first dummy contact and a second dummy contact. The substrate has a memory device region and a peripheral region. The first dielectric layer is disposed on the substrate. The storage node contact is disposed in the first dielectric layer in the memory device region. The first dummy contact is disposed in the first dielectric layer in the memory device region and is adjacent to a boundary between the memory device region and the peripheral region. The second dummy contact is disposed in the first dielectric layer in the memory device region and is located between the first dummy contact and the storage node contact. The second dummy contact includes a second dielectric layer and a conductive layer located on the second dielectric layer.

In an embodiment of the semiconductor structure of the present invention, a thickness of the conductive layer in the second dummy contact does not exceed half of a thickness of the second dummy contact.

In an embodiment of the semiconductor structure of the present invention, the first dummy contact includes the second dielectric layer.

In an embodiment of the semiconductor structure of the present invention, the storage node contact includes the conductive layer.

In an embodiment of the semiconductor structure of the present invention, the semiconductor structure further includes a word line structure disposed in the substrate in the memory device region.

In an embodiment of the semiconductor structure of the present invention, the semiconductor structure further includes a dummy word line structure disposed in the substrate in the memory device region and located between the word line structure and the boundary between the memory device region and the peripheral region.

The manufacturing method of the semiconductor structure of the present invention includes the following steps. A substrate having a memory device region and a peripheral region is provided. A first dielectric layer is formed on the substrate. A storage node contact, a first dummy contact and a second dummy contact are formed in the first dielectric layer in the memory device region, wherein the first dummy contact is adjacent to a boundary between the memory device region and the peripheral region, and the second dummy contact is located between the first dummy contact and the storage node contact. The second dummy contact includes a second dielectric layer and a conductive layer located on the second dielectric layer.

In an embodiment of the manufacturing method of the semiconductor structure of the present invention, a forming method of the storage node contact, the first dummy contact and the second dummy contact includes the following steps. A first dielectric material layer formed of a first dielectric material is formed on the substrate in the memory device region. A plurality of dielectric pillars formed of a second dielectric material are formed on the first dielectric material layer, wherein positions of the plurality of dielectric pillars correspond to positions of the storage node contact, the first dummy contact and the second dummy contact. A second dielectric material layer formed of the first dielectric material is formed on the first dielectric material layer to cover the first dielectric material layer and the plurality of dielectric pillars and fill the spaces between the dielectric pillars. A part of the second dielectric material layer is removed to expose a top surface of the first dielectric material layer and top surfaces of the plurality of dielectric pillars. A part of each of the dielectric pillars corresponding to positions of the storage node contact and the second dummy contact is removed. The remaining dielectric pillar corresponding to the position of the storage node contact is removed. A position of the removed dielectric pillar is filled with the conductive layer.

In an embodiment of the manufacturing method of the semiconductor structure of the present invention, a method for removing the part of each of the dielectric pillars corresponding to the positions of the storage node contact and the second dummy contact includes the following steps. A first mask layer is formed on the second dielectric material layer, wherein the first mask layer covers the peripheral region and the dielectric pillar corresponding to the position of the first dummy contact. A first wet etching process is performed using the first mask layer as an etching mask. The first mask layer is removed.

In an embodiment of the manufacturing method of the semiconductor structure of the present invention, an etchant used in the first wet etching process includes buffer hydrogen fluoride.

In an embodiment of the manufacturing method of the semiconductor structure of the present invention, a thickness of each of the remaining dielectric pillars is more than half of a thickness of each of the dielectric pillars after the first wet etching process.

In an embodiment of the manufacturing method of the semiconductor structure of the present invention, a method for removing the remaining dielectric pillar corresponding to the position of the storage node contact includes the following steps. A second mask layer is formed on the second dielectric material layer, wherein the second mask layer covers the peripheral region and positions corresponding to the first dummy contact and the second dummy contact. A second wet etching process is performed using the second mask layer as an etching mask. The second mask layer is removed.

In an embodiment of the manufacturing method of the semiconductor structure of the present invention, an etchant used in the second wet etching process includes buffer hydrogen fluoride.

In an embodiment of the manufacturing method of the semiconductor structure of the present invention, the manufacturing method further includes forming a word line structure and a dummy word line structure in the substrate in the memory device region before forming the first dielectric layer, wherein the dummy word line structure is located between the word line structure and the boundary between the memory device region and the peripheral region.

Based on the above, in the manufacturing process of the semiconductor structure of the present invention, since the mask layer extends downward into the second dummy contact hole, during removing the dielectric layer in the storage node contact hole, the etchant may be effectively prevented from penetrating into the first dummy contact hole and causing damage to the first dummy contact, and therefore the second dummy contact composed of a dielectric layer and a conductive layer may be formed between the first dummy contact and the storage node contact.

### BRIEF DESCRIPTION OF THE DRAWINGS

FIGS. 1A to 1F are schematic cross-sectional views of the manufacturing process of the semiconductor structure of the embodiment of the present invention.

### DESCRIPTION OF THE EMBODIMENTS

The embodiments are listed below and described in detail with the accompanying drawings, but the provided embodiments are not intended to limit the scope of the present invention. In addition, the drawings are for illustration purposes only and are not drawn to original scale. In order to facilitate understanding, the same devices will be described with the same symbols in the following descriptions.

In the text, the terms mentioned in the text, such as “comprising”, “including”, “containing” and “having” are all open-ended terms, i.e., meaning “including but not limited to”.

When using terms such as “first” and “second” to describe elements, it is only used to distinguish the elements from each other, and does not limit the order or importance of the devices. Therefore, in some cases, the first element may also be called the second element, the second element may also be called the first element, and this is not beyond the scope of the present invention.

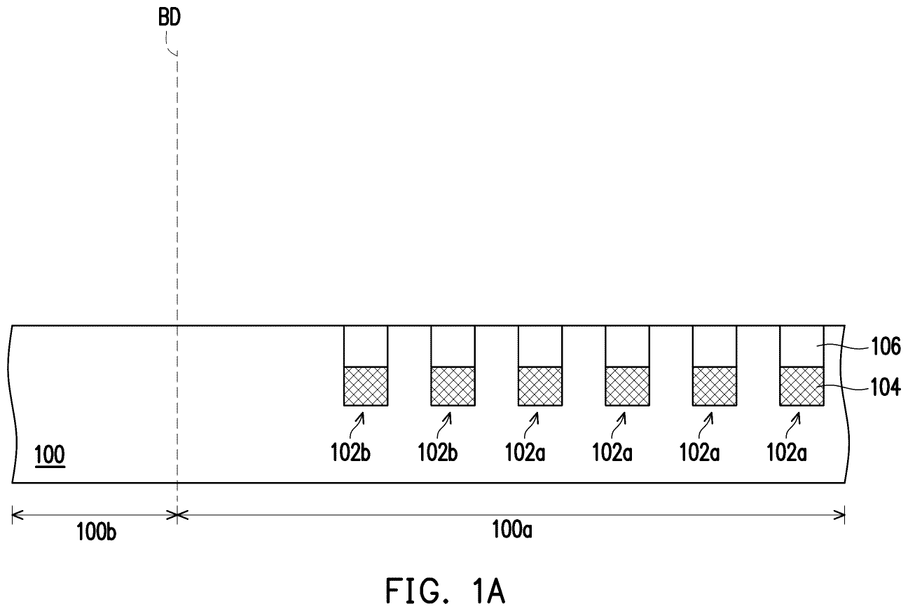

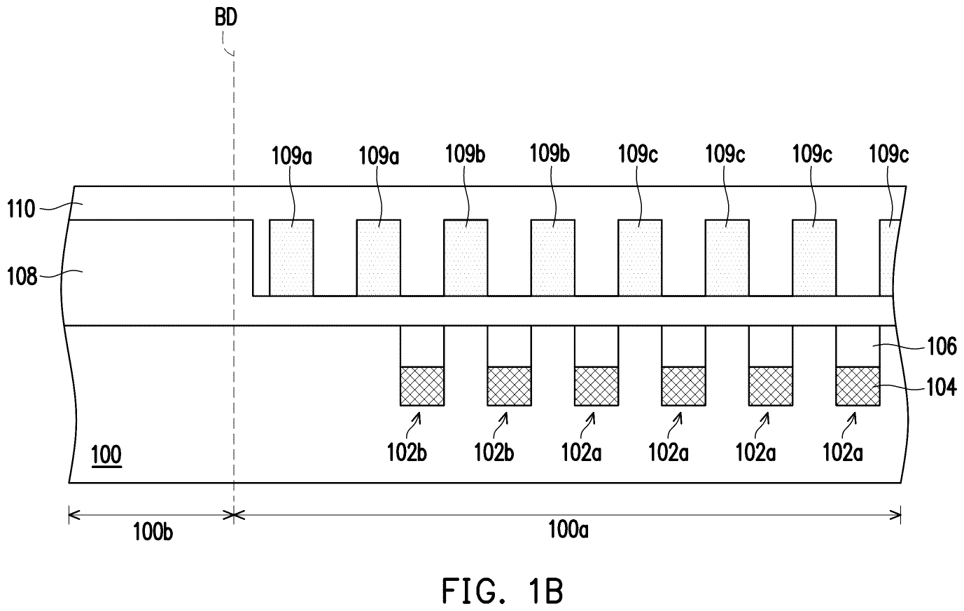

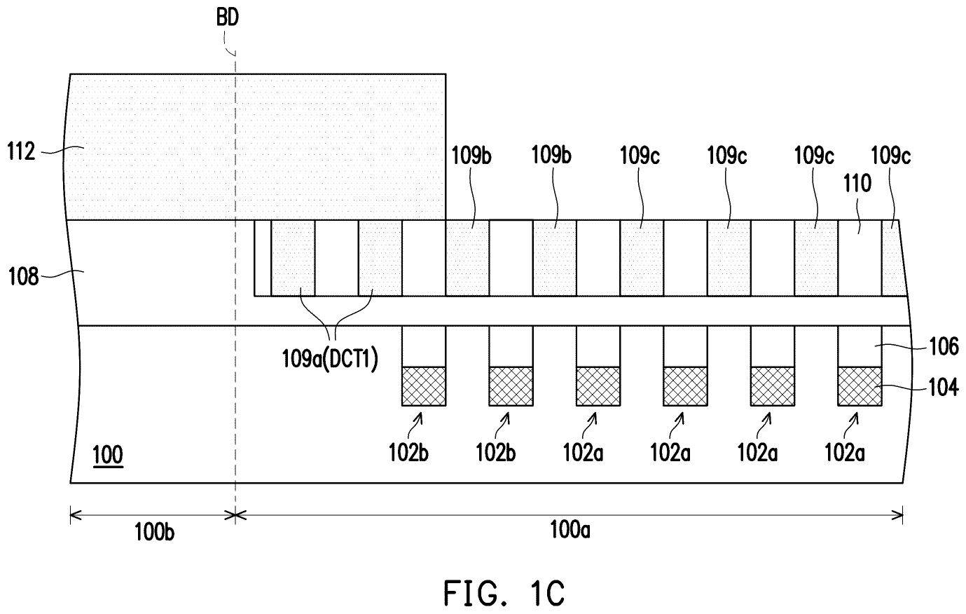

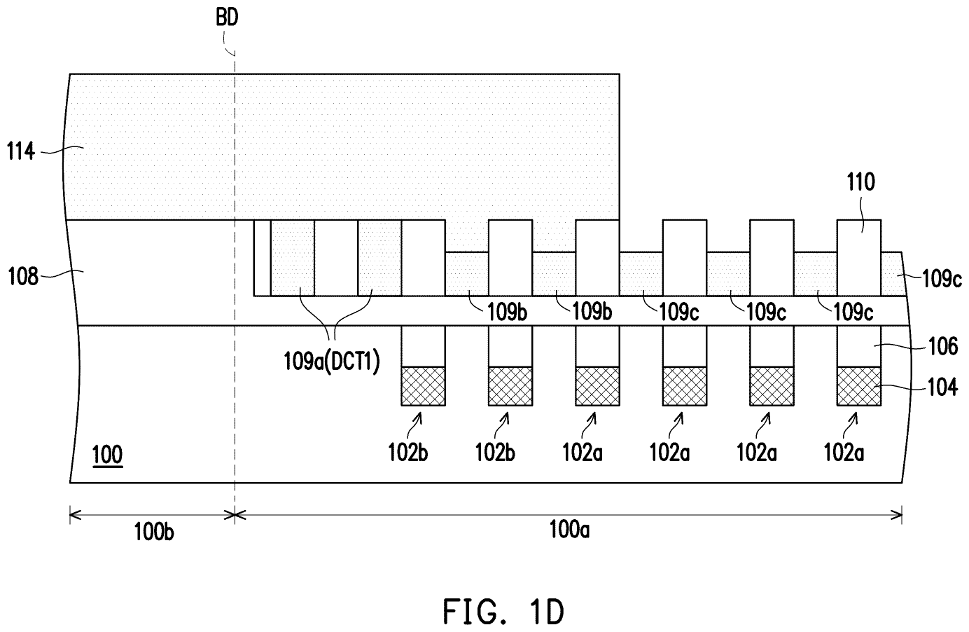

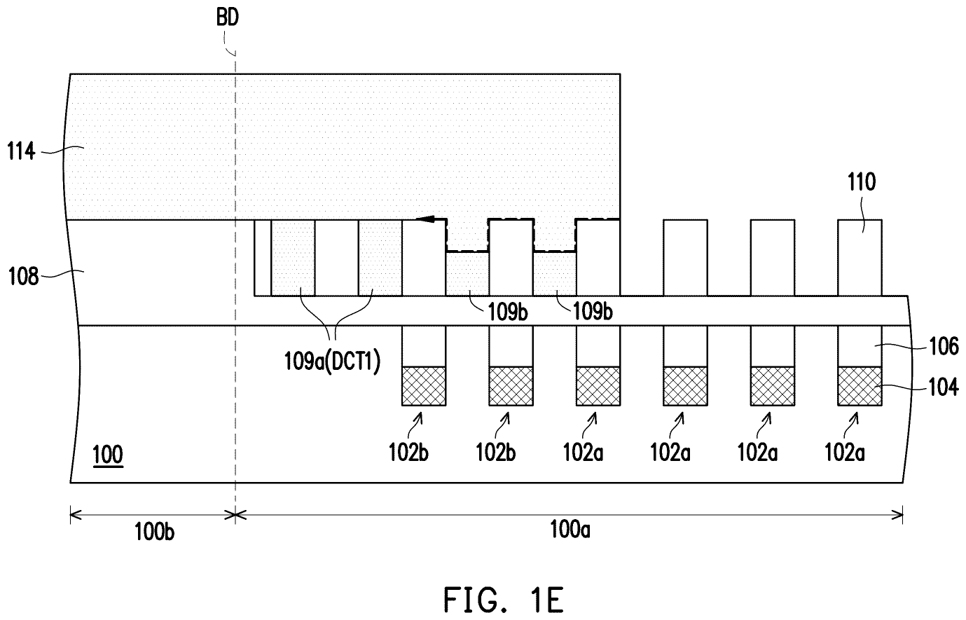

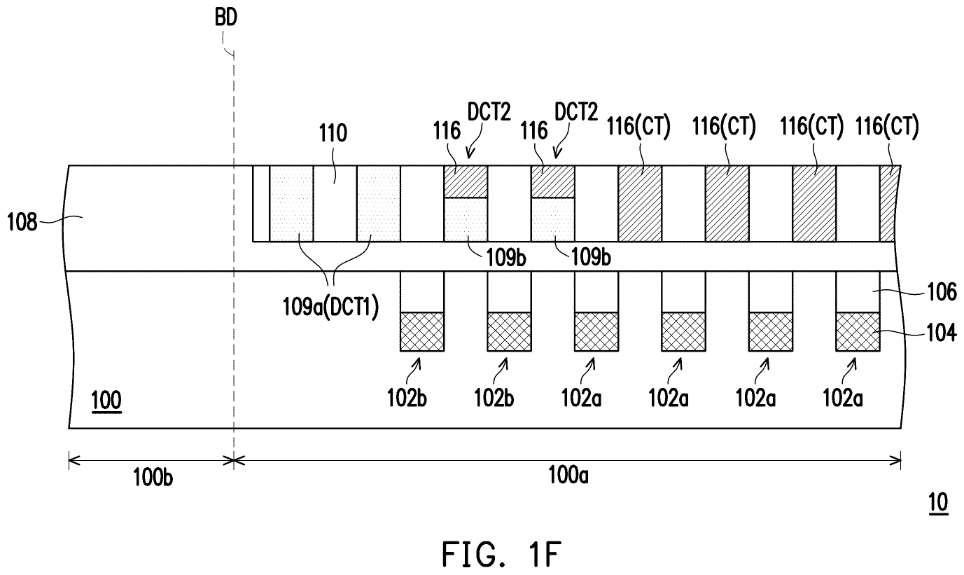

FIGS. 1A to 1F are schematic cross-sectional views of the manufacturing process of the semiconductor structure of the embodiment of the present invention.

Referring to FIG. 1A, a substrate 100 is provided. In the present embodiment, the substrate 100 is a silicon substrate, but the present invention is not limited thereto. The substrate 100 has a memory device region 100a and a peripheral region 100b surrounding the memory device region 100a. There is a boundary BD between the memory device region 100a and the peripheral region 100b. In the present embodiment, the peripheral region 100b may be a region in which the device other than the memory device is to be formed, and the device other than the memory device may be the logic device, the circuit pattern, etc., but the present invention is not limited thereto.

Then, word line structures 102a and dummy word line structures 102b may be formed in substrate 100 in memory device region 100a. The dummy word line structures 102b are located between the word line structures 102a and the boundary BD between the memory device region 100a and the peripheral region 100b.

In FIG. 1A, the number of the word line structures 102a and the number of the dummy word line structures 102b are only exemplary, and the present invention is not limited thereto. In other embodiments, the dummy word line structures 102b may be omitted according to actual needs.

In the present embodiment, the word line structures 102a and the dummy word line structures 102b may each include a conductive layer 104 and an insulating layer 106 located on the conductive layer 104. The conductive layer 104 in the word line structure 102a serves as a word line, which is also known as a buried word line. The forming methods of the word line structure 102a and the dummy word line structure 102b are well known to those skilled in the art and will not be described here. In addition, depending on actual needs, other required devices (not shown) may be formed on the substrate 100 in the peripheral region 100b.

Referring to FIG. 1B, a first dielectric material layer 108 formed of a first dielectric material is formed on the substrate 100. In the present embodiment, the first dielectric material is silicon nitride, but the present invention is not limited thereto. The first dielectric material layer 108 covers the word line structures 102a and the dummy word line structures 102b located in the memory device region 100a and various devices (not shown) located in the peripheral region 100b. In addition, in the present embodiment, the thickness of the first dielectric material layer 108 in the peripheral region 100b is greater than the thickness of the first dielectric material layer 108 in the memory device region 100a, but the present invention is not limited thereto. In other embodiments, the thickness of the first dielectric material layer 108 in the peripheral region 100b may be equal to the thickness of the first dielectric material layer 108 in the memory device region 100a.

Next, dielectric pillars 109a, dielectric pillars 109b and dielectric pillars 109c formed of a second dielectric material are formed on the first dielectric material layer 108 and respectively correspond to the positions of first dummy contacts, second dummy contacts and storage node contacts to be formed. In the present embodiment, the second dielectric material is silicon oxide.

In FIG. 1B, the numbers of the dielectric pillars 109a, 109b, and 109c are only exemplary, and the present invention is not limited thereto.

In the present embodiment, the forming method of the dielectric pillars 109a, the dielectric pillars 109b and the dielectric pillars 109c may include the following steps. First, a dielectric layer formed of the second dielectric material is formed on the first dielectric material layer 108 in the memory device region 100a. Then, a patterning process is performed on the dielectric layer. Therefore, in the present embodiment, the bottom surfaces of the dielectric pillars 109a, the dielectric pillars 109b and the dielectric pillars 109c may be located at the same level, and the top surfaces of the dielectric pillars 109a, the dielectric pillars 109b and the dielectric pillars 109c may also be located at the same level. That is, the dielectric pillars 109a, the dielectric pillars 109b and the dielectric pillar 109c may have the same thickness.

In addition, in the present embodiment, the dielectric pillars 109c corresponding to the positions of the storage node contacts to be formed may be located at the center of the memory device region 100a, the dielectric pillars 109a corresponding to the positions of the first dummy contacts to be formed are adjacent to the boundary BD between the memory device region 100a and the peripheral region 100b, and the dielectric pillars 109b corresponding to the positions of the second dummy contact to be formed are located between the dielectric pillars 109a and the dielectric pillars 109c.

After the dielectric pillars 109a, the dielectric pillars 109b and the dielectric pillars 109c are formed, a second dielectric material layer 110 formed of the first dielectric material is formed on the first dielectric material layer 108. The second dielectric material layer 110 covers the first dielectric material layer 108, the dielectric pillars 109a, the dielectric pillars 109b and the dielectric pillars 109c, and fills the spaces between the dielectric pillars 109a, dielectric pillar 109b and dielectric pillars 109c.

Referring to FIG. 1C, a part of the second dielectric material layer 110 is removed to expose the top surface of the first dielectric material layer 108, the top surfaces of the dielectric pillars 109a, the top surfaces of the dielectric pillars 109b and the top surfaces of the dielectric pillars 109c. In the present embodiment, the method for removing a part of the second dielectric material layer 110 is, for example, performing an etching process, but the present invention is not limited thereto. In this way, the first dielectric material layer 108 and the second dielectric material layer 110 may be regarded as a first dielectric layer formed on the substrate 100, and the dielectric pillars 109a, dielectric pillars 109b and dielectric pillars 109c may be regarded as a second dielectric layer formed in the first dielectric layer. In addition, the dielectric pillars 109a may serve as first dummy contacts DCT1 in the semiconductor structure of the present embodiment.

After that, a first mask layer 112 is formed on the second dielectric material layer 110. In the present embodiment, the first mask layer 112 is a photoresist layer, but the present invention is not limited thereto. The first mask layer 112 covers the peripheral region 100b and the first dummy contacts DCT1. In other words, the first mask layer 112 is located in the entire peripheral region 100b and extends from the peripheral region 100b to the memory device region 100a to cover the first dummy contacts DCT1.

Referring to FIG. 1D, using the first mask layer 112 as the etching mask, a first wet etching process is performed to remove a part of each of the dielectric pillars 109b and a part of each of the dielectric pillars 109c.

In the present embodiment, the material of the dielectric pillars 109a, the dielectric pillars 109b and the dielectric pillars 109c is silicon oxide, and the material of the first dielectric material layer 108 and the second dielectric material layer 110 is silicon nitride, so the etchant used in the first wet etching process may be buffer hydrogen fluoride, which has a higher etching rate for silicon oxide and a lower etching rate for silicon nitride. In this way, in the first wet etching process, the second dielectric material layer 110 may only be slightly removed, or even hardly removed.

In addition, in the present embodiment, the thickness of the dielectric pillar 109b and the thickness of the dielectric pillar 109c removed by the first wet etching process do not exceed half of the thickness of the entire dielectric pillar. In other words, after the first wet etching process, the thickness of dielectric pillar 109b and the thickness of dielectric pillar 109c are more than half of the thickness of the entire dielectric pillar. In this way, the impact on the capacitance value of the bit line formed in the subsequent process may be avoided.

In addition, in the present embodiment, the thickness of the dielectric pillar 109b and the thickness of the dielectric pillar 109c removed by the first wet etching process do not exceed half of the thickness of the entire dielectric pillar, that is, the time of the first wet etching process may not be too long. Therefore, even if the etchant used in the first wet etching process penetrates through the interface between the first mask layer 112 and the second dielectric material layer 110, it may not cause serious damage to the first dummy contacts DCT1.

Afterwards, the first mask layer 112 is removed, and a second mask layer 114 is formed on the second dielectric material layer 110. In the present embodiment, the second mask layer 114 is a photoresist layer, but the present invention is not limited thereto. The second mask layer 114 covers the peripheral region 100b, the first dummy contacts DCT1 and the remaining dielectric pillars 109b. In other words, the second mask layer 114 is located in the entire peripheral region 100b, extends from the peripheral region 100b to the memory device region 100a to cover the first dummy contacts DCT1 and fills in the positions of the removed parts of the dielectric pillars 109b.

Referring to FIG. 1E, using the second mask layer 114 as the etching mask, a second wet etching process is performed to remove the remaining dielectric pillars 109c. Same as the first etching process, buffer hydrogen fluoride is used as an etchant in the second etching process to remove the remaining dielectric pillars 109c.

In the present embodiment, even if the etchant used in the second wet etching process penetrates through the interface between the second mask layer 114 and the second dielectric material layer 110, since the second mask layer 114 fills in the positions of the removed parts of the dielectric pillars 109b, the path length that the etchant penetrates increases, as shown by the dotted arrow in FIG. 1E). Therefore, the etchant may hardly reach the first dummy contacts DCT1, thus causing no damage to the first dummy contacts DCT1, and may only slightly remove the remaining dielectric pillars 109b.

Referring to FIG. 1F, the second mask layer 114 is removed. Then, a conductive layer 116 is filled in the positions of the removed parts of dielectric pillars 109b and the positions of removed dielectric pillars 109c. The method for filling the conductive layer 116 may include the following steps. First, a conductive material layer is formed on the second dielectric material layer 110 to fill the positions of the removed parts of dielectric pillars 109b and the positions of removed dielectric pillars 109c. Afterwards, the conductive material layer on the top surface of the second dielectric material layer 110 is removed. The remaining dielectric pillars 109b and the conductive layer 116 above form second dummy contacts DCT2, and the conductive layer 116 filling the positions of the removed dielectric pillars 109c forms storage node contacts CT. In this way, a semiconductor structure 10 of the present embodiment is formed.

In other embodiments, the second dummy contacts DCT2 may be constituted by the conductive layer 116 and another conductive layer. The forming method is well known to those skilled in the art and will not be described here.

During the manufacturing process of the semiconductor structure 10 of the present embodiment, since the second mask layer 114 extends downward to the top surfaces of the remaining dielectric pillars 109b, the etchant may be effectively prevented from penetrating to the first dummy contacts DCT1 and damaging the first dummy contacts DCT1 during removing the dielectric pillars 109c.

In addition, during the manufacturing process of the semiconductor structure 10 of the present embodiment, since the second mask layer 114 extends downward to the top surfaces of the remaining dielectric pillars 109b, the second dummy contacts DCT2 composed of the dielectric pillars 109b and the conductive layer 116 may be formed between the first dummy contacts DCT1 and the storage node contacts CT.

In other embodiments, depending on the number of the dielectric pillars 109b, the thickness of the dielectric pillars 109b removed by the first wet etching process may be adjusted to avoid the etchant used in the first wet etching process from causing serious damage to the first dummy contacts DCT1. For example, when the number of the dielectric pillars 109b is large, the thickness of the dielectric pillars 109b removed by the first wet etching process may be smaller. In this way, the damage caused by the etchant to the first dummy contacts DCT1 may still be avoided by increasing the path length of etchant penetration.

It will be apparent to those skilled in the art that various modifications and variations may be made to the disclosed embodiments without departing from the scope or spirit of the disclosure. In view of the foregoing, it is intended that the disclosure covers modifications and variations provided that they fall within the scope of the following claims and their equivalents.

What is claimed is:

1. A semiconductor structure, comprising:
a substrate, having a memory device region and a peripheral region;
a first dielectric layer, disposed on the substrate;
a storage node contact, disposed in the first dielectric layer in the memory device region;
a first dummy contact, disposed in the first dielectric layer in the memory device region, and adjacent to a boundary between the memory device region and the peripheral region; and
a second dummy contact, disposed in the first dielectric layer in the memory device region, and located between the first dummy contact and the storage node contact,
wherein the second dummy contact comprises a second dielectric layer and a conductive layer located on the second dielectric layer.

2. The semiconductor structure of claim 1, wherein a thickness of the conductive layer in the second dummy contact does not exceed half of a thickness of the second dummy contact.

3. The semiconductor structure of claim 1, wherein the first dummy contact comprises the second dielectric layer.

4. The semiconductor structure of claim 1, wherein the storage node contact comprises the conductive layer.

5. The semiconductor structure of claim 1, further comprising a word line structure, disposed in the substrate in the memory device region.

6. The semiconductor structure of claim 5, further comprising a dummy word line structure, disposed in the substrate in the memory device region, and located between the word line structure and the boundary between the memory device region and the peripheral region.

7. A manufacturing method of a semiconductor structure, comprising:
providing a substrate having a memory device region and a peripheral region;
forming a first dielectric layer on the substrate; and
forming a storage node contact, a first dummy contact and a second dummy contact in the first dielectric layer in the memory device region, wherein the first dummy contact is adjacent to a boundary between the memory device region and the peripheral region, and the second dummy contact is located between the first dummy contact and the storage node contact,
wherein the second dummy contact comprises a second dielectric layer and a conductive layer located on the second dielectric layer.

8. The manufacturing method of claim 7, wherein a forming method of the storage node contact, the first dummy contact and the second dummy contact comprises:
forming a first dielectric material layer formed of a first dielectric material on the substrate in the memory device region;
forming a plurality of dielectric pillars formed of a second dielectric material on the first dielectric material layer, wherein positions of the plurality of dielectric pillars correspond to positions of the storage node contact, the first dummy contact and the second dummy contact;
forming a second dielectric material layer formed of the first dielectric material on the first dielectric material layer to cover the first dielectric material layer and the plurality of dielectric pillars and fill the spaces between the dielectric pillars;
removing a part of the second dielectric material layer to expose a top surface of the first dielectric material layer and top surfaces of the plurality of dielectric pillars;
removing a part of each of the dielectric pillars corresponding to positions of the storage node contact and the second dummy contact;
removing the remaining dielectric pillar corresponding to the position of the storage node contact; and
filling a position of the removed dielectric pillar with the conductive layer.

9. The manufacturing method of claim 8, wherein a method for removing the part of each of the dielectric pillars corresponding to the positions of the storage node contact and the second dummy contact comprises:
forming a first mask layer on the second dielectric material layer, wherein the first mask layer covers the peripheral region and the dielectric pillar corresponding to the position of the first dummy contact;
performing a first wet etching process using the first mask layer as an etching mask; and
removing the first mask layer.

10. The manufacturing method of claim 9, wherein an etchant used in the first wet etching process comprises buffer hydrogen fluoride.

11. The manufacturing method of claim 9, wherein a thickness of each of the remaining dielectric pillars is more than half of a thickness of each of the dielectric pillars after the first wet etching process.

12. The manufacturing method of claim 8, wherein a method for removing the remaining dielectric pillar corresponding to the position of the storage node contact comprises:
forming a second mask layer on the second dielectric material layer, wherein the second mask layer covers the peripheral region and positions corresponding to the first dummy contact and the second dummy contact;
performing a second wet etching process using the second mask layer as an etching mask; and
removing the second mask layer.

13. The manufacturing method of claim 12, wherein an etchant used in the second wet etching process comprises buffer hydrogen fluoride.

14. The manufacturing method of claim 7, further comprising forming a word line structure and a dummy word line structure in the substrate in the memory device region before forming the first dielectric layer, wherein the dummy word line structure is located between the word line structure and the boundary between the memory device region and the peripheral region.
